(19) United States
(12) Patent Application Publication
(10) Pub. No.: US 2010/0090302 A1
(43) Pub. Date: Apr. 15, 2010

(54) RESONATOR

(75) Inventors: Viet Nguyen Hoang, Leuven (BE); Dirk Gravesteijn, Waalre (NL); Radu Surdeanu, Roosbeek (BE)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP, B.V., Eindhoven (NL)

(21) Appl. No.: 12/444,684

(22) PCT Filed: Oct. 5, 2007
(86) PCT No.: PCT/IB07/54071

§ 371 Date: Apr. 7, 2009

(30) Foreign Application Priority Data
Oct. 9, 2006 (EP) 06122002.6

(51) Int. Cl. H01L 23/28; H01L 21/336; H01L 21/31

(52) U.S. Cl. 257/428; 438/151; 438/781; 438/57; 257/E21.415; 257/E21.24; 257/E23.116

(57) ABSTRACT

A method of making a resonator, preferably a nano-resonator, includes starting with a FINFET structure with a central bar, first and second electrodes connected to the central bar, and third and fourth electrodes on either side of the central bar and separated from the central bar by gate dielectric. The structure is formed on a buried oxide layer. The gate dielectric and buried oxide layer are then selectively etched away to provide a nano-resonator structure with a resonator element 30, a pair of resonator electrodes (32,34), a control electrode (36) and a sensing electrode (38).

The invention relates to a resonator and a method of making it, and in particular to a nano resonator.

Resonators are required in radio frequency (RF) circuits. A traditional resonator is a quartz crystal, which provides a high quality (q-) factor resonator. However, such resonators are bulky discrete devices which makes them less suitable for compact mobile applications. A smaller resonator would be preferable.

For this reason, microelectromechanical systems (MEMS) resonators have been investigated. These have a q-factor comparable to a good quartz resonator and have a much smaller form factor. They have the additional advantage that they can be mass-produced using silicon technology and so they can be made at relatively low cost.

However, MEMS resonators have some disadvantages. They are discrete devices, which are not fully compatible with CMOS processing. They require a relatively high operation voltage, for example about 10V, compared with the voltage required for standard CMOS operation of about 1.2V. A relevant parameter is motional resistance, which is the ratio between the input voltage and output current of the resonator. The motional resistance of such resonators is relatively high (MO), and the resonant frequency relatively low. These factors limit circuit design freedom and increase power consumption.

A number of other resonator structures have been proposed. One example is described in WO 02/078075 which describes a fabrication method for semiconductor devices that may be used to manufacture a bridge over a trench. The bridge may be free to oscillate. The approach used has a number of disadvantages. Most importantly, the method described uses a wafer bonding step which makes processing much more complicated and makes the method incompatible with standard CMOS processes. Secondly, the approach used to form the bridge is lithography followed by reactive ion etching (RIE) which limits the spacing of the elements.

Thus, there remains a need for a resonator overcoming some or all of these disadvantages.

According to the invention, there is provided a method of making a resonator according to claim 1.

The method is a straightforward route to manufacturing resonators that may be extremely small, and closely spaced to their electrodes, in a way that is compatible with conventional processing. This is unlike the approach of WO02/078075 that requires a wafer bonding step which is not normally present in conventional manufacturing lines. Further, the size of the gaps can be as low as the thickness of gate oxide. Gate oxide can be manufactured to very precise thicknesses and so the method according to the invention can deliver very precise spacings of the electrodes from the resonator.

The invention also relates to a method of manufacturing a semiconductor device including such a resonator, by:

providing a substrate;

forming a buried oxide layer on the substrate;

forming a resonator on the substrate in a resonator region of the substrate using the above method and forming at least one active device on at least one active device region of the substrate;

depositing and patterning a thermal decomposable polymer over the resonator region;

depositing a permeable dielectric layer over the active device region and over thermal decomposable polymer over the resonator region;

heating the device to decompose the thermal decomposable polymer to form a second cavity.

In another aspect, the invention relates to a device according to claim 9.

For a better understanding of the invention, embodiments will now be described, purely by way of example, with reference to the accompanying drawings, in which:

FIG. 1 shows a side view of a step in the manufacture of a resonator according to the invention;

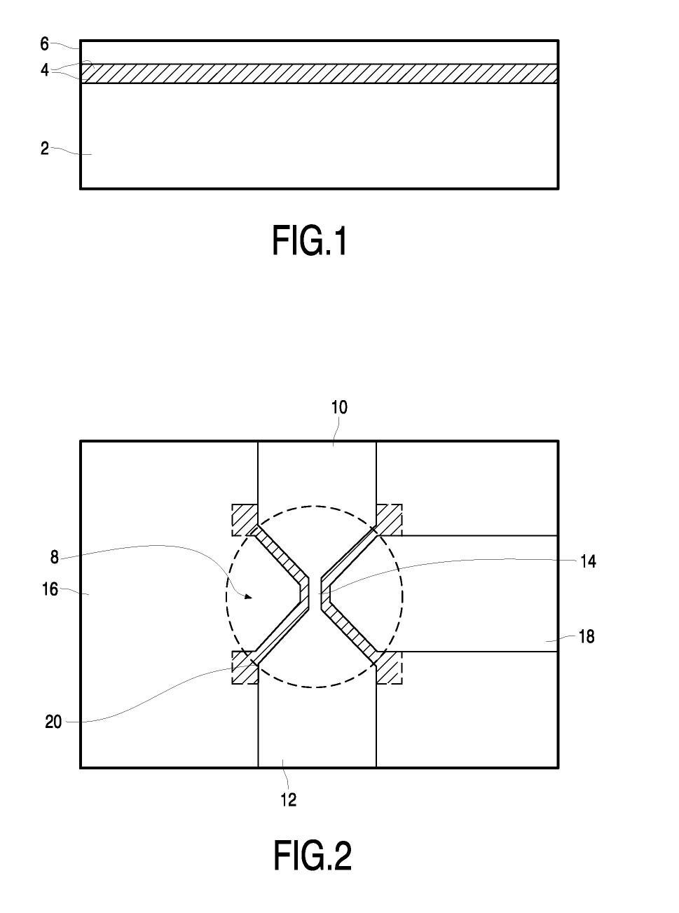

FIG. 2 shows a top view of the step of FIG. 1;

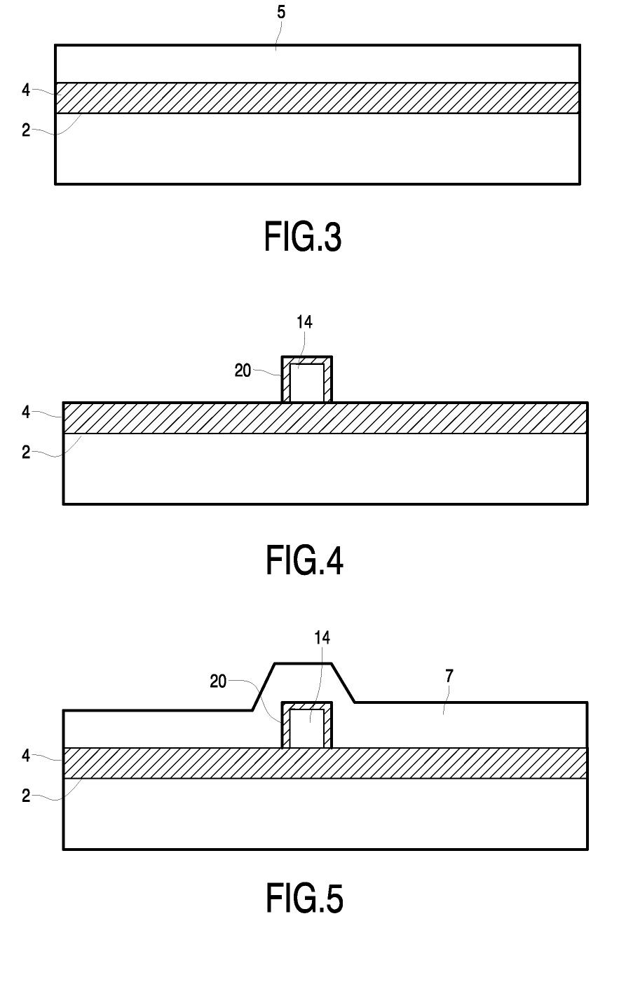

FIGS. 3 to 5 show side views of intermediate steps used to reach the step shown in FIG. 1;

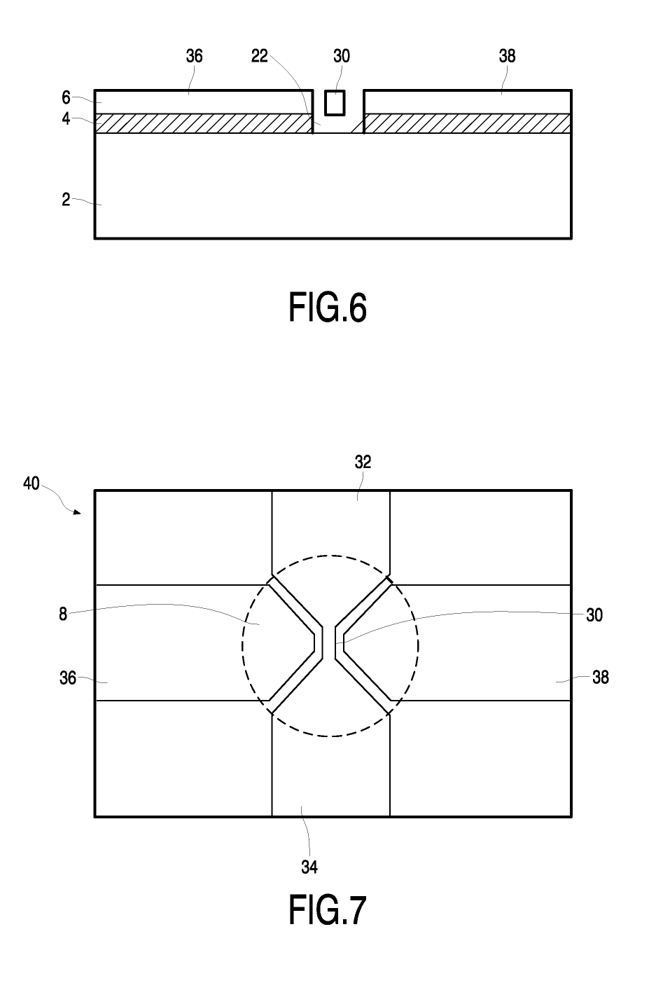

FIG. 6 shows a side view of a subsequent step in the method;

FIG. 7 shows a top view of the step of FIG. 6;

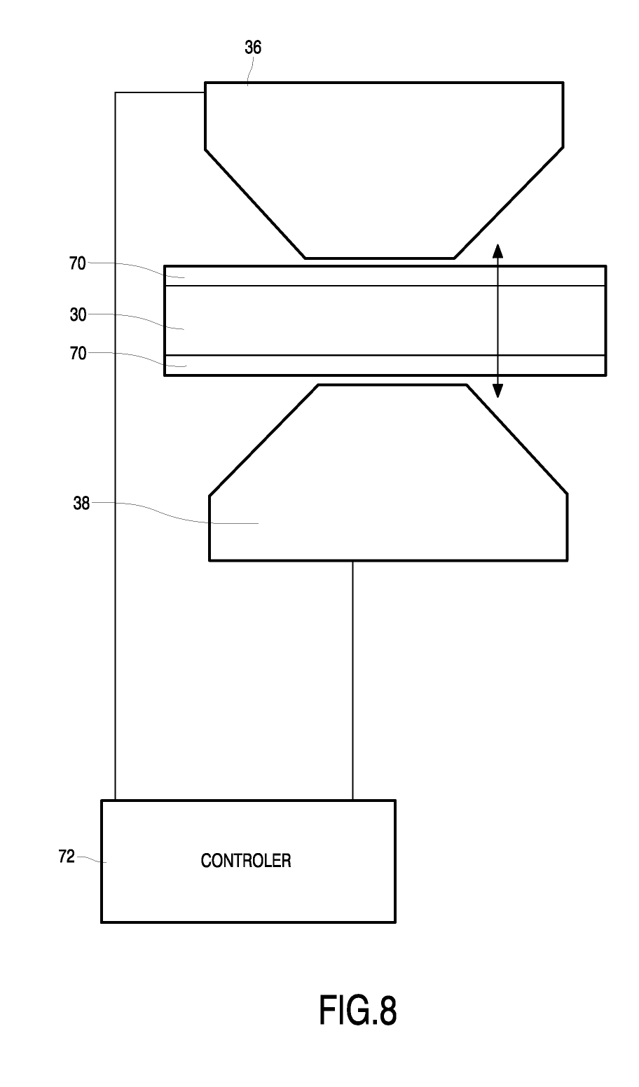

FIG. 8 shows a resonator with a gas sensitive layer; and

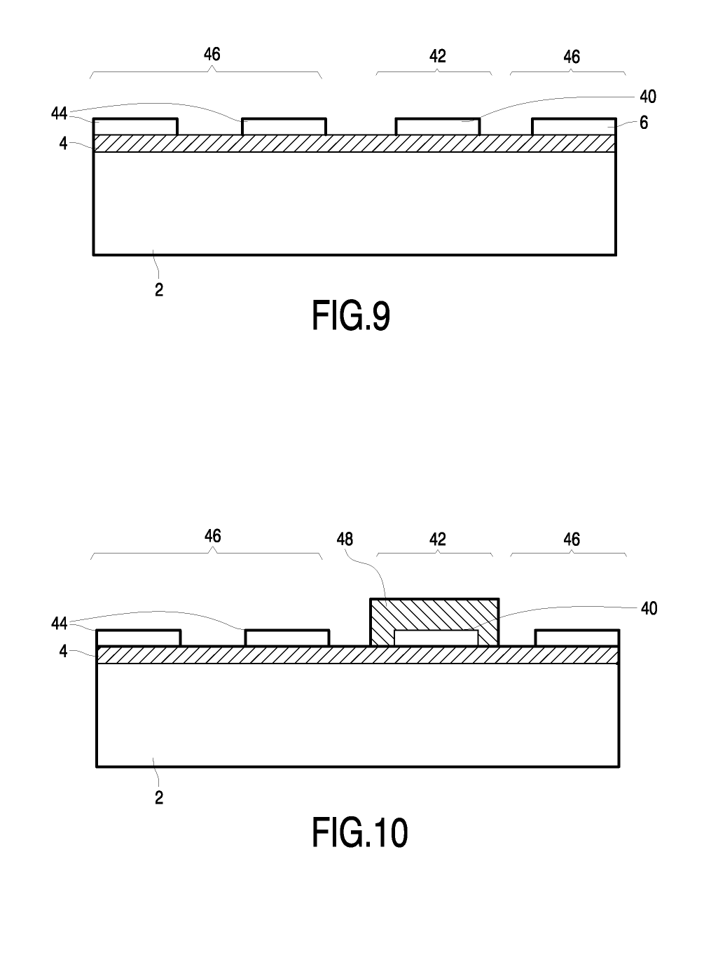

FIGS. 9 to 14 show side views in the manufacture of an integrated device including the resonator.

Like or similar components are give the same reference numerals in the different figures, which are schematic and not to scale.

Referring to FIGS. 1 and 2, a structure is formed on a semiconductor substrate 2 with an oxide layer 4 formed thereon. A semiconductor layer 6 is formed over the buried oxide layer 4. In the embodiment, both the substrate and the semiconductor layer 6 are of silicon.

The semiconductor layer 6 is patterned to form a FINFET (fin-Field effect transistor) structure as shown in FIG. 2. Such a structure includes first and second electrodes 10, 12 both of which taper in a central region 8 and which connect to a narrow central bar 14. In a FINFET acting as such, the first and second electrodes (10,12) are the source and drain.

The FINFET structure also includes third and fourth electrodes 16,18 which likewise taper in the central region 8 and which surround the central bar 14. The third and fourth electrodes 16, 18 are arranged on either side of the central bar 14 and spaced from it by thin insulating oxide 20. These third and fourth electrodes 16,18 act as gate electrodes when the FINFET is used as such.

A number of approaches are known to making such FINFET structures. Note that the invention does not require the FINFET structure to operate as such, and the term FINFET structure is accordingly used in the present invention to describe a like structure to a FINFET such as, for example, the structure illustrated in FIGS. 1 and 2, or other similar structures with a narrow channel extending longitudinally spaced by lateral insulator from opposed gate electrodes.

The process flow may be the following, as illustrated in FIGS. 3 to 5.

A SiO₂ layer 4 is formed on a Si wafer 2. A first semiconductor layer 5 of 65 nm (100) Si layer is then deposited on the SiO₂ layer as shown in FIG. 3. This layer is then patterned using a 60 nm thick SiON hard mask to form the first and second electrodes.

Next, the wafer is surface cured by dry oxidation and annealing in a reducing atmosphere. An oxide layer 20 of silicon dioxide is then deposited. This step is illustrated in FIG. 4.

Amorphous silicon as second semiconductor layer 7 is then deposited to a thickness of 200 nm and etched back to 140 nm as illustrated in FIG. 5. A 60 nm oxide is then deposited and patterned to form a hard mask which is then used to pattern the third and fourth electrodes to define them in the amorphous silicon layer over the first and second electrodes.

An implantation step is then carried out using a tilted process of As for NMOS or BF₂ for PMOS. The hard mask forming the third and fourth electrodes is then removed. At this stage, there is still amorphous silicon over the top of the central bar since it is not possible to pattern the third and fourth electrodes to stop exactly at the edge of the central bar 14.

A CMP step is then carried out to remove this amorphous silicon and hence form the structure of FIGS. 1 and 2.

Referring to FIGS. 6 and 7, a selective etch step is then used to etch away oxide in the central region 8, removing both the buried oxide layer 4 under the central region to form cavity 22 and the insulating layer 20 from either side of the central bar which thus forms a free resonator element 30. Any suitable selective etch may be used, including for example buffered HF.

The resonator element 30 is connected to the first and second electrodes 10,12 which form resonator anchor 32,34. The third electrode 16 becomes the control electrode 36 spaced from the resonator element 30 and the fourth electrode 18 becomes the sense electrode 38 likewise spaced from the resonator element.

Since the gap between the third and fourth electrodes 16,18 and the resonator element 30 is defined by the thickness of the gate oxide, it can be very precisely defined. In particular, in embodiments the gap may be controlled to an accuracy of 0.1 nm and hence very small gaps can be accurately defined.

In use, the control electrode may be used to induce vibration in the resonator element to force it to resonate. The sensing electrode can measure induced current which reaches its maximum value at the resonant frequency.

The gate oxide in the FINFET structure can be very small, in the range 1 nm to 1 μm, but typically towards the lower end of this range, preferably less than 100 nm, further preferably less than 10 nm. One benefit of the invention is that this oxide thickness determines the gap between the resonator 30 and the electrodes 36,38 which is accordingly highly controllable.

A further benefit is that when the gap is small only a small voltage is needed to drive the resonator and further a large induced current is achievable.

The method allows the size of the resonator element to be easily adjusted, for example over the range 10 nm to several pm during the lithographic steps manufacturing the FINFET structure and this in turn means that the resonant frequency can be adjusted over a wide range as required. in particular, the method should achieve resonant frequencies up to several tens of GHz which is well above the frequency achieved in MEMS resonator. Preferably, the maximum thickness and width of the central bar is less than 500 nm, further preferably less than 200 nm, and further preferably less than 100 nm, which can deliver a motional resistance of a few Ω or less.

All this results in a low power device that can be included in complex circuits.

One application of the device is as a sensor. A gas-sensitive layer 70 is coated on the resonator 30 (FIG. 8) and when a gas molecule is absorbed onto the gas sensitive layer 70 it changes the total mass of the resonator and hence the resonant frequency. The frequency shift is measured by detector 72 and this provides a measure of the concentration of the gas. The small size of the resonator 30 allows for high resolution detection, for example for an electronic nose for security applications.

The resonator, whether or not an electronic nose, may be integrated into a CMOS device, as illustrated in FIGS. 9 to 14. Referring to FIG. 9, CMOS active devices 44 are manufactured in semiconductor layer 6 in active device regions 46, and a resonator 40 is manufactured in resonator region 42 as described above with reference to FIGS. 1 to 7.

Then, a thermal decomposable polymer (TDP) 48 is deposited over the entire surface and patterned to be present in the resonator region 42 (FIG. 10). Normally, the TDP is removed from the active device regions 46 but this is not essential and if TDP is required over part of these active device regions 46 it may be applied there in the same steps.

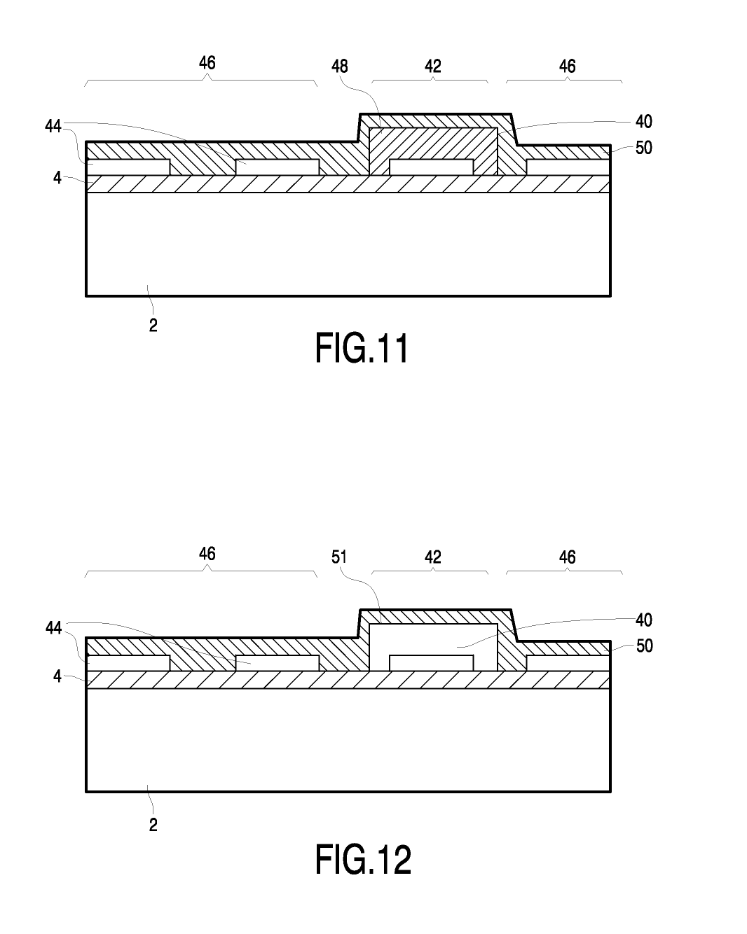

A permeable dielectric layer 50 is then deposited over the whole surface, i.e. over the TDP 48 where present and the active devices 44 in active device regions 46 (FIG. 11).

A heating step is then used to decompose the TDP 48 leaving a second cavity 51 under the dielectric layer 50 over the resonator 40 (FIG. 12).

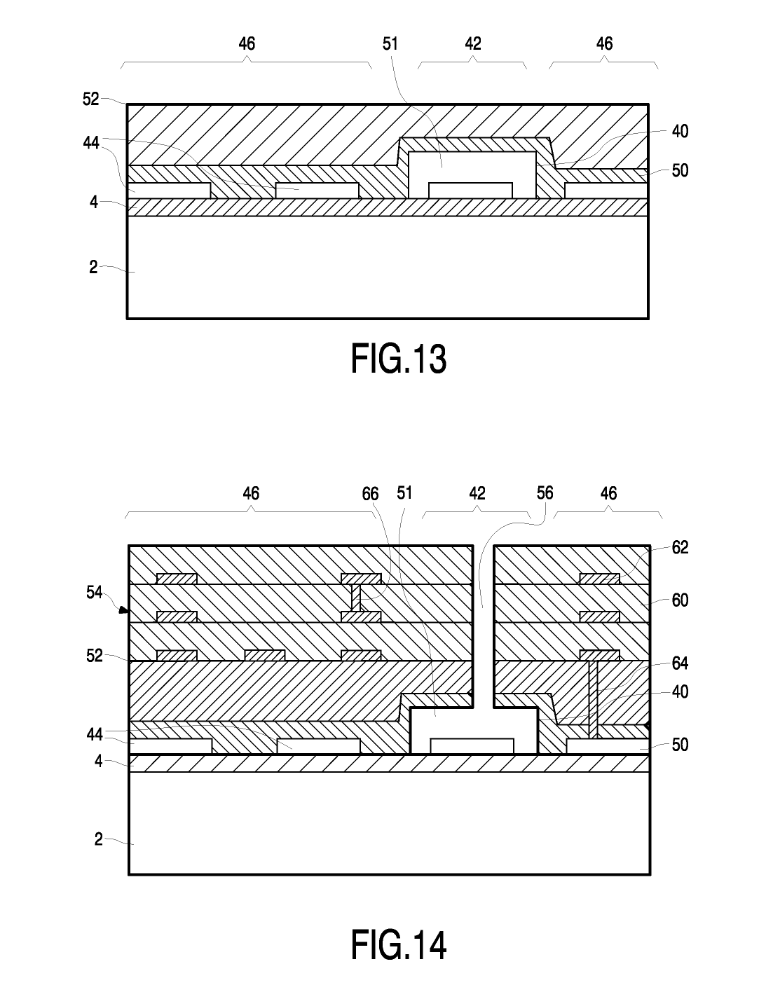

A premetal dielectric (PMD) layer 52 is then deposited over the surface and planarised, in the embodiment described using a chemical-mechanical polishing (CMP) step (FIG. 13). Other planarisation methods may also be used if preferred. The PMD layer 52 and dielectric layer 50 effectively encapsulate the resonator 40.

Then, a multilayer metallisation 54 is deposited. This includes a number of insulating dielectric layers 60, horizontal interconnect metallisation 62, as well as vias 64 connecting to the active devices 44 and also vias 66 connecting different levels of the multilevel metallisation. Connections to the resonator may be by lateral interconnections (not shown) over the buried oxide layer 4.

For applications requiring the resonator to be in contact with the surroundings, for example in measurement applications, an additional step is then provided to etch opening 56 from the upper surface of the multilayer metallisation 54 though the PMD layer 52 and dielectric layer 50 to cavity 51. This opening may be used, for example, in the chemical sensor approach of FIG. 8. This step of creating the opening 56 may be omitted for applications in which the resonator does not need to be in contact with the surroundings.

This results in the arrangement shown in FIG. 14. The device may now be finished and packaged as is known in the art.

Those skilled in the art will realise that the above embodiment may be varied. For example, the semiconductor material need not be silicon, and a large variety of manufacturing steps may be introduced as required. In particular, the devices 44 need not be CMOS devices but may be any semiconductor devices as required.

1. A method of manufacturing a resonator, comprising:
forming a Fin-Field Effect Transistor (FINFET) structure with a substrate, a buried oxide layer on the substrate, a semiconductor layer on the buried oxide layer, the semiconductor layer being patterned to define four semiconductor regions coming together in a central region, the four regions including opposed first and second regions linked by a central bar and opposed third and fourth regions on either side of the central bar, with oxide insulator between each the third and fourth regions and the central bar; and
selectively etching the buried oxide layer and the oxide insulator in the central region to form a cavity under the central bar and to etch away the oxide insulator between the third and fourth regions and the central bar so that the central bar forms a resonator element, the first and second regions form resonator anchors, and the third and fourth regions form control and sensing electrodes.

2. A method according to claim 1 wherein the step of forming a FINFET structure includes:
forming a first semiconductor layer on the buried oxide layer;
patterning the first semiconductor layer to form the first and second regions and the central bar;
depositing the oxide insulator on the central bar;
depositing a second semiconductor layer; and
patterning the second semiconductor layer to form the third and fourth region on either side of the central region separated from the central bar by the oxide insulator.

3. A method according to claim 2, wherein the step of pattering the second semiconductor layer includes carrying out a chemical mechanical polishing step to remove the second semiconductor layer above a predetermined level to remove the second semiconductor layer from above the central bar.

4. A method according claim 2 wherein the steps of patterning at least one of the first semiconductor layer and the second semiconductor layer include forming a hard mask, patterning the hard mask and then using the hard mask to etch the respective semiconductor layer.

5. A method of manufacturing a semiconductor device including a resonator, the method comprising:
providing a substrate;
forming a buried oxide layer on the substrate;
forming a resonator on the substrate in a resonator region of the substrate using a method according to claim 1 and forming at least one active device on at least one active device region of the substrate;
depositing and patterning a thermal decomposable polymer over the resonator region;
depositing a permeable dielectric layer over the active device region and over thermal decomposable polymer over the resonator region;
heating the device to decompose the thermal decomposable polymer to form a second cavity.

6. A method of manufacturing a semiconductor device including a resonator according to claim 5 further comprising, after the step of heating the device to decompose the thermal decomposable polymer, depositing a premetal dielectric over the permeable dielectric layer, and planarising the premetal dielectric by chemical-mechanical polishing.

7. A method of manufacturing a semiconductor device including a resonator according to claim 6 further comprising forming a multi-layer metallisation over the premetal dielectric.

8. A method according to claim 5 further comprising etching an opening from the upper surface of the semiconductor device through the permeable dielectric layer to the second cavity to expose the cavity.

9. A resonator, comprising
a substrate having a first major surface extending longitudinally and laterally;
an insulating layer on the first major surface of the substrate, the insulating layer defining a cavity;
a pair of resonator electrodes longitudinally spaced on the insulating layer on either side of the cavity;
a resonator element linking the resonator electrodes and spanning the cavity;
a control electrode laterally spaced from and on one side of the resonator element;
a sensing electrode laterally spaced from and on the other side of the resonator element from the control electrode;
wherein spacing between the control electrode and the resonator element is less than about 100 nm and the spacing between the sensing electrode and the resonator element is less than about 100 nm.

10. A semiconductor device, including:
a resonator according to claim 9 on a resonator region of the substrate; and
at least one active device on at least one active device region on the substrate; and
an encapsulant over the resonator region and active device region, the encapsulant defining a cavity, the resonator being in the cavity.

11. A semiconductor device according to claim 10, further comprising a multilayer metalisation over the active device region.

12. A semiconductor device according to claim 10 further comprising an opening through the encapsulant linking the cavity to the outside.
